(19) United States
(12) Patent Application Publication
(10) Pub. No.: US 2026/0059753 A1
(43) Pub. Date: Feb. 26, 2026

(54) SEMICONDUCTOR DEVICE AND METHOD OF MANUFACTURING THE SAME

(71) Applicant: Kioxia Corporation, Tokyo (JP)

(72) Inventor: Yusuke SASAKI, Yokkaichi Mie (JP)

(21) Appl. No.: 19/063,010

(22) Filed: Feb. 25, 2025

(30) Foreign Application Priority Data
Aug. 26, 2024 (JP) 2024-144437

(51) Int. Cl. H10B 43/27; H10B 41/27

(52) U.S. Cl. CPC H10B 43/27; H10B 41/27

(57) ABSTRACT

A semiconductor device includes a substrate; a stacked film provided above the substrate and including a plurality of insulating layers and a plurality of electrode layers alternately stacked in a first direction intersecting an upper surface of the substrate; and a columnar portion penetrating through the stacked film in the first direction. A concentration of a Group V element of at least one first one of the insulating layers on a first end side in the first direction is higher than a concentration of the Group V element of a second one of the insulating layers.

### CROSS-REFERENCE TO RELATED APPLICATION

This application is based upon and claims the benefit of priority from Japanese Patent Application No. 2024-144437, filed Aug. 26, 2024, the entire contents of which are incorporated herein by reference.

### FIELD

Embodiments described herein relate generally to a semiconductor device and a method of manufacturing the same.

### BACKGROUND

When a variation in a width of a memory hole (i.e., a columnar portion) between an upper end side and a lower end side of the memory hole is large, a variation in a threshold voltage of a memory cell between an upper end side and a lower end side of the memory cell becomes large.

### DESCRIPTION OF THE DRAWINGS

FIG. 1 is a cross-sectional view showing a configuration example of a semiconductor device according to a first embodiment.

FIG. 2 is a cross-sectional view showing a columnar portion of the semiconductor device according to the first embodiment.

FIG. 3 is a cross-sectional view taken along III-III in FIG. 2 showing the columnar portion of the semiconductor device according to the first embodiment.

FIG. 4 is a cross-sectional view showing a method of manufacturing the semiconductor device according to the first embodiment.

FIGS. 5A and 5B are cross-sectional views showing a detailed method of manufacturing the semiconductor device according to the first embodiment.

FIGS. 6A and 6B are cross-sectional views showing the method of manufacturing the semiconductor device according to the first embodiment following FIGS. 5A and 5B.

FIG. 7 is a cross-sectional view showing a method of manufacturing a semiconductor device according to a comparative example.

FIG. 8 is a detailed cross-sectional view of a stacked film illustrated in FIGS. 6A and 6B.

FIGS. 9A and 9B are cross-sectional views showing the method of manufacturing the semiconductor device according to the first embodiment following FIGS. 6A and 6B.

FIG. 10 is a cross-sectional view showing an insulating layer on a lower end side in a semiconductor device according to a second embodiment.

FIGS. 11A and 11B are cross-sectional views showing prevention of leakage current by the semiconductor device according to the second embodiment.

FIG. 12 is a cross-sectional view showing a semiconductor device according to a third embodiment.

### DETAILED DESCRIPTION

Embodiments provide a semiconductor device and method of manufacturing the same that can reduce a variation in a width of a memory hole.

In general, according to one embodiment, a semiconductor device includes a substrate; a stacked film provided above the substrate and including a plurality of insulating layers and a plurality of electrode layers alternately stacked in a first direction intersecting an upper surface of the substrate; and a columnar portion penetrating through the stacked film in the first direction. A concentration of a Group V element of at least one first one of the insulating layers on a first end side in the first direction is higher than a concentration of the Group V element of a second one of the insulating layers.

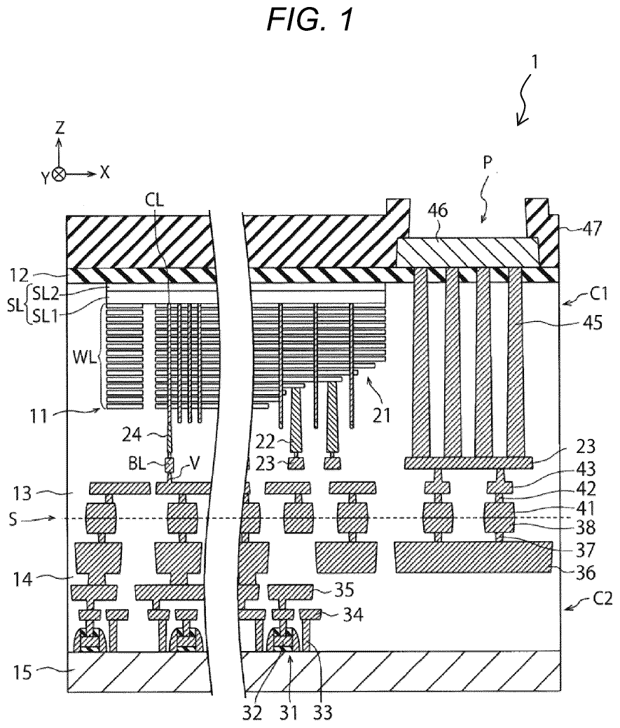

Hereinafter, embodiments of the present disclosure will be described with reference to the drawings. In FIGS. 1 to 12, the same or similar configurations are denoted by the same reference numerals, and redundant description will be omitted.

### First Embodiment

FIG. 1 is a cross-sectional view illustrating a configuration example of a semiconductor device according to a first embodiment. A semiconductor device 1 illustrated in FIG. 1 is a three-dimensional memory in which an array chip C1 and a circuit chip C2 are stuck together. The semiconductor device 1 has a CMOS directly bonded to array (CBA) structure.

The array chip C1 includes a memory cell array 11 including a plurality of memory cells arranged three-dimensionally, an insulating film 12 on the memory cell array 11, and an interlayer insulating film 13 below the memory cell array 11. The insulating film 12 is, for example, a silicon oxide film or a silicon nitride film. The interlayer insulating film 13 is, for example, a silicon oxide film, or a stacked film including a silicon oxide film and another insulating film.

The circuit chip C2 is provided under the array chip C1. The circuit chip C2 functions as a control circuit (logic circuit) that controls an operation of the array chip C1. The circuit chip C2 includes an interlayer insulating film 14 and a substrate 15 below the interlayer insulating film 14. The interlayer insulating film 14 is, for example, a silicon oxide film or a stacked film including a silicon oxide film and another insulating film. The substrate 15 is, for example, a semiconductor substrate such as a silicon substrate. FIG. 1 illustrates the X-direction and the Y-direction which are parallel to a surface, i.e., an upper surface, of the substrate 15 and perpendicular to each other, and the Z-direction which is perpendicular to the upper surface of the substrate 15. The Z-direction is an example of a first direction. The X-direction and the Y-direction are an example of a second direction intersecting the first direction.

The array chip C1 includes a plurality of word lines WL, a plurality of columnar portions CL, and a source line SL, as a plurality of electrode layers in the memory cell array 11. The word lines WL are an example of a conductive layer. A staircase structure portion 21 is provided at an end portion of the memory cell array 11 in the X-direction. Each word line WL is electrically connected to a wiring layer 23 via a contact plug 22. The plurality of columnar portions CL penetrate the plurality of word lines WL in the Z-direction. Each columnar portion CL is electrically connected to a bit line BL in the same layer as the wiring layer 23 via a via plug 24. Each columnar portion CL is also electrically connected to the source line SL. The source line SL includes a first layer SL1, which is a semiconductor layer, and a second layer SL2, which is a metal layer. A wiring layer 43 including a via plug V is provided under the bit line BL. A via plug 42 is provided under the wiring layer 43. A plurality of metal pads 41 are provided under the via plugs 42. The metal pad 41 is, for example, a copper (Cu) layer or an aluminum (Al) layer.

The array chip C1 further includes a plurality of via plugs 45 provided on the wiring layer 23, metal pads 46 provided on the via plugs 45 and on the insulating film 12, and a passivation film 47 provided on the metal pads 46 and on the insulating film 12. The metal pads 46 are, for example, a Cu layer or an Al layer, and function as external connection pads (bonding pads) of the semiconductor device of FIG. 1. The passivation film 47 is, for example, an insulating film such as a silicon oxide film. The passivation film 47 has an opening P that exposes the upper surface of the metal pad 46. The metal pad 46 may be connected to a mounting substrate or other device via an opening P by a bonding wire, a solder ball, a metal bump, or the like.

The circuit chip C2 includes a plurality of transistors 31. Each transistor 31 includes a gate electrode 32 provided on the substrate 15 via a gate insulating film, and a source diffusion layer and a drain diffusion layer (not illustrated) provided in the substrate 15. The circuit chip C2 also includes a plurality of contact plugs 33 provided on the source diffusion layer or drain diffusion layer of the transistor 31, a wiring layer 34 provided on the contact plugs 33 and including a plurality of wirings, and a wiring layer 35 provided on the wiring layer 34 and including a plurality of wirings.

The circuit chip C2 further includes a wiring layer 36 provided on the wiring layer 35 and including a plurality of wirings, a plurality of via plugs 37 provided on the wiring layer 36, and a plurality of metal pads 38 provided on the via plugs 37. The metal pads 38 are provided under the metal pads 41 of the array chip C1.

The circuit chip C2 is stuck to the array chip C1 on a sticking surface S. Specifically, the interlayer insulating film 13 of the array chip C1 and the interlayer insulating film 14 of the circuit chip C2 are stuck on the sticking surface S. The metal pads 41 of the array chip C1 and the metal pads 38 of the circuit chip C2 are also bonded to each other on the sticking surface S. With this configuration, the array chip C1 and the circuit chip C2 are electrically connected to each other via the metal pads 38 and 41.

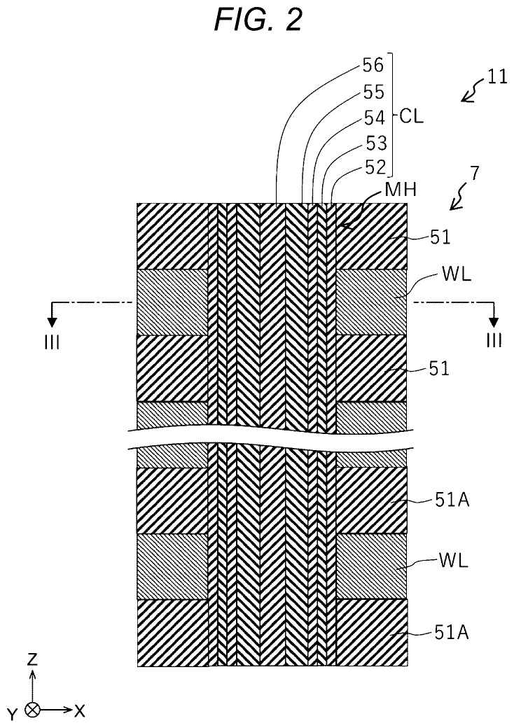

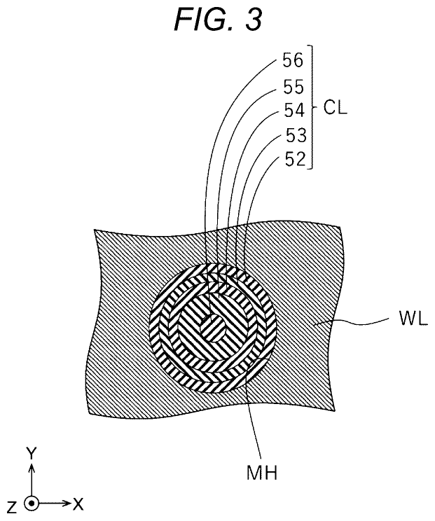

FIG. 2 is a cross-sectional view illustrating a structure of the columnar portion CL in the semiconductor device according to the first embodiment. FIG. 3 is a cross-sectional view taken along III-III in FIG. 2 illustrating the structure of the columnar portion CL in the semiconductor device according to the first embodiment.

As illustrated in FIG. 2, the memory cell array 11 includes a plurality of word lines WL and a plurality of insulating layers 51 and 51A alternately stacked on the interlayer insulating film 13 (FIG. 1). That is, the memory cell array 11 includes a stacked film 7 in which the plurality of word lines WL and the plurality of insulating layers 51 and 51A are alternately and repeatedly stacked. The word lines WL contain, for example, tungsten (W) as a main component. The word lines WL may contain transition elements other than tungsten, such as molybdenum (Mo), titanium (Ti), and niobium (Nb). The insulating layers 51 and 51A are mainly made up of silicon oxide (SiO₂). However, as described below, the insulating layer 51A on the lower end side and the insulating layer 51 on the upper layer side differ from each other in the concentration of a group V element.

The columnar portion CL is provided on the stacked film 7 to penetrate in the Z-direction. That is, the columnar portion CL is provided inside a memory hole MH that penetrates the stacked film 7 in the Z-direction. In the example illustrated in FIG. 3, a cross section of the columnar portion CL has a circular shape. The columnar portion CL includes a block insulating film 52, a charge storage film 53, a tunnel insulating film 54, a channel semiconductor film 55, and a core insulating film 56 in this order. The charge storage film 53 is, for example, a silicon nitride film. The charge storage film 53 is formed on side surfaces of the word line WL and the insulating layer 51 via the block insulating film 52. The charge storage film 53 may be a semiconductor layer such as a polysilicon layer. The channel semiconductor film 55 is, for example, a polysilicon layer. The channel semiconductor film 55 is formed on a side surface of the charge storage film 53 via the tunnel insulating film 54. The block insulating film 52, the tunnel insulating film 54, and the core insulating film 56 are, for example, a silicon oxide film or a metal insulating film.

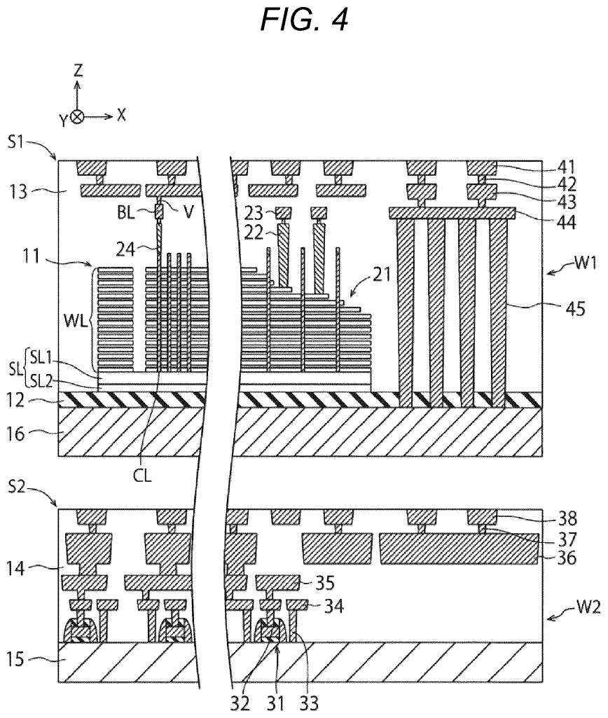

In order to ensure a sufficient etching rate in wet etching to widen the memory hole MH even after heat treatment of the substrate 16 (see FIG. 4), a concentration of the Group V element of the insulating layer 51A on the lower end side (i.e., bottom side) among the plurality of insulating layers 51 and 51A is higher than that of the insulating layers 51 on the upper layer side other than the insulating layer 51A on the lower end side. The insulating layer 51A is an example of a first insulating layer. The insulating layer 51 is an example of a second insulating layer. The Group V element is also called a Group 15 element. As the Group V element, for example, phosphorus (P) can be suitably used.

The number of insulating layers 51A on the lower end side is, for example, ten to fifteen insulating layers counting from the lowermost insulating layer. The number of insulating layers 51A on the lower end side may be about one-tenth of the number of the insulating layers on the lower end side among the plurality of insulating layers 51 and 51A.

In the example illustrated in FIG. 2, the Group V element is contained (i.e., doped) in the insulating layer 51A on the lower end side, but is not contained in the insulating layer 51 on the upper layer side. That is, in the example illustrated in FIG. 2, the concentration of the Group V element in the insulating layer 51 on the upper layer side is 0(%). By making the insulating layer 51A on the lower end side contain the Group V element, the etching rate of wet etching can be locally increased at a lower end portion (i.e., bottom portion) of the memory hole MH. With this configuration, a diameter of the memory hole MH (i.e., a bottom diameter) can be increased at the lower end portion of the memory hole MH. By increasing the diameter of the memory hole MH at the lower end portion of the memory hole MH, tapering of the memory hole MH can be reduced. That is, the variation in the width of the memory hole MH between the upper end side and the lower end side of the memory hole MH can be reduced.

The concentration of the Group V element of the insulating layer 51A on the lower end side may be 1.9% or more. Here, the higher the concentration of phosphorus (P) in the silicon oxide film (SiO₂), the higher the etching rate of the silicon oxide film using diluted hydrofluoric acid. By setting the concentration of the Group V element to 1.9% or more, the insulating layer 51A on the lower end side can maintain a sufficient etching rate in wet etching even after heat treatment such as annealing that reduces warpage of the substrate 16 is performed. Specifically, by setting the concentration of the Group V element to 1.9% or more, the etching rate of the insulating layer 51A on the lower end side can be increased to an etching rate equivalent to the etching rate of a sacrifice layer 57A on the lower end side (i.e., a SiN film containing oxygen) described below. With this configuration, not only the variation in the width of the memory hole MH between the upper and lower insulating layers 51 and 51A, but also the variation in the width of the memory hole MH between the insulating layer 51A and the sacrifice layer 57A (i.e., the word line WL) can be reduced. Therefore, the tapering of the memory hole MH can be further reduced.

The concentration of the Group V element of the insulating layer 51A on the lower end side may be 3.5% or less. By setting the concentration of Group V element to 3.5% or less, the leakage current between the word lines WL caused by the Group V element can be reduced. Specifically, by setting the concentration of the Group V element to 3.5% or less, the leakage current between the word lines WL can be reduced to be less than the leakage current when a low-density silicon oxide film (SiO₂), which will be described below, is used as the insulating layer 51A.

Next, a method of manufacturing the semiconductor device 1 having the configuration described above will be described. FIG. 4 is a cross-sectional view illustrating a method of manufacturing the semiconductor device 1 according to the first embodiment. FIG. 4 illustrates an array wafer W1 including a plurality of array chips C1 before dicing, and a circuit wafer W2 including a plurality of circuit chips C2 before dicing. The array wafer W1 is also called a memory wafer, and the circuit wafer W2 is also called a CMOS wafer.

The orientation of the memory wafer W1 in FIG. 4 is opposite to the orientation of the array chip C1 in FIG. 1. FIG. 4 illustrates the memory wafer W1 before orientation thereof is reversed for sticking. The array wafer W1 and the circuit wafer W2 are stuck together and diced to manufacture the semiconductor device 1 illustrated in FIG. 1. That is, FIG. 1 illustrates the array chip C1 after the orientation thereof is reversed for sticking and stuck and diced.

In FIG. 4, the symbol S1 indicates an upper surface of the memory wafer W1. The symbol S2 indicates an upper surface of the circuit wafer W2. The memory wafer W1 includes a substrate 16 provided under the insulating film 12. The substrate 16 is, for example, a semiconductor substrate such as a silicon substrate. The substrate 16 is an example of a second substrate.

In the first embodiment, first, as illustrated in FIG. 4, the memory cell array 11, the insulating film 12, the interlayer insulating film 13, the staircase structure portion 21, and the metal pad 41 are formed on the substrate 16 of the memory wafer W1. The interlayer insulating film 14, the transistor 31, and the metal pad 38 are formed on the substrate 15 of the circuit wafer W2. In this case, a via plug 45, a wiring layer 44, a wiring layer 43, a via plug 42, and a metal pad 41 are formed in this order on the substrate 16. A contact plug 33, a wiring layer 34, a wiring layer 35, a wiring layer 36, a via plug 37, and a metal pad 38 are formed in this order on the substrate 15. Next, the array wafer W1 and the circuit wafer W2 are stuck together by mechanical pressure. With this configuration, the interlayer insulating film 13 and the interlayer insulating film 14 are adhered together. Subsequently, the array wafer W1 and the circuit wafer W2 are annealed, for example, at 400° C. With this configuration, the metal pad 41 and the metal pad 38 are joined together.

After that, the substrate 15 is thinned by Chemical Mechanical Polishing (CMP), the substrate 16 is removed by the CMP, and the array wafer W1 and the circuit wafer W2 are cut into a plurality of chips. In this way, the semiconductor device 1 illustrated in FIG. 1 is manufactured. The metal pad 46 and the passivation film 47 illustrated in FIG. 1 are formed on the insulating film 12, for example, after thinning of the substrate 15 and removal of the substrate 16.

FIG. 1 illustrates a boundary surface between the interlayer insulating film 13 and the interlayer insulating film 14 and a boundary surface between the metal pad 41 and the metal pad 38, but these boundary surfaces are generally not observed after the annealing described above. However, positions where these boundary surfaces exist can be estimated by detecting, for example, an inclination of the side surface of the metal pad 41 or the side surface of the metal pad 38, or a positional deviation between the side surface of the metal pad 41 and the metal pad 38.

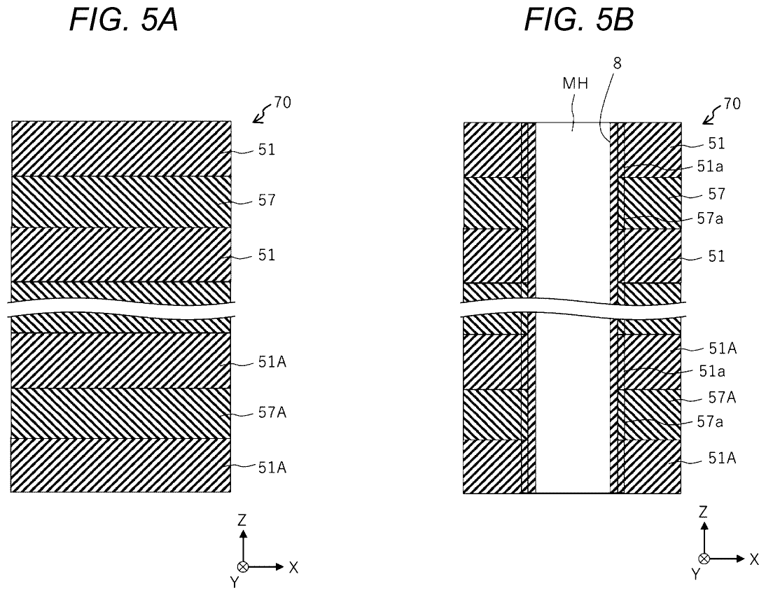

FIGS. 5A and 5B are cross-sectional views illustrating a detailed method of manufacturing the semiconductor device 1 according to the first embodiment. More specifically, first, as illustrated in FIG. 5A, the stacked film 70 is formed by alternately stacking a plurality of insulating layers 51 and 51A and a plurality of sacrifice layers 57 and 57A above the substrate 16 (see FIG. 4). The stacked film 70 is an example of a second stacked film. In the example illustrated in FIGS. 5A and 5B, the insulating layer 51A on the lower end side is, for example, a silicon oxide film (SiO₂) containing phosphorus (P), which is a Group V element. The insulating layer 51 on the upper end side is, for example, a silicon oxide film (SiO₂) not containing phosphorus (P).

The insulating layer 51A on the lower end side is formed to contain phosphorus (P) by, for example, a plasma Chemical Vapor Deposition (CVD) method using silane (SiH₄) gas and helium-diluted phosphine gas (PH₃/He). Here, the higher the flow rate of the PH₃/He gas, the higher the concentration of phosphorus (P) contained in the silicon oxide film (SiO₂). Therefore, by adjusting the flow rate of the PH₃/He gas, the concentration of phosphorus (P) contained in the insulating layer 51A on the lower end side can be appropriately adjusted. On the other hand, the insulating layer 51 on the upper layer side is formed so as not to contain phosphorus (P) by, for example, a plasma CVD method using silane (SiH₄) gas.

The sacrifice layer 57 is a layer to be replaced by the word line WL. The sacrifice layer 57A on the lower end side is, for example, a silicon nitride film (SiN) that contains oxygen. The sacrifice layer 57 on the upper layer side is, for example, a silicon nitride film (SiN) that does not contain oxygen. The sacrifice layer 57A on the lower end side is formed to contain oxygen by, for example, a plasma CVD method using SiH₂Cl₂ gas, NH₃ gas, and N₂O gas. By forming the sacrifice layer 57 to contain oxygen, the etching rate of the wet etching of the sacrifice layer 57A on the lower end side can be increased. The sacrifice layer 57 on the upper layer side is formed so as not to contain oxygen, for example, by a plasma CVD method using SiH₂Cl₂ gas and NH₃ gas.

After forming the stacked film 70, as illustrated in FIG. 5B, the memory hole MH is formed to penetrate the stacked film 70. In the example illustrated in FIG. 5B, the memory hole MH is formed by a lithography method and a Reactive Ion Etching (RIE) method using fluorocarbon (CF)-based etching gas. The formation of the memory hole MH by the RIE method proceeds in the depth direction (−Z-direction) of the memory hole MH while protecting side walls of the insulating layers 51 and 51A and the sacrifice layers 57 and 57A with a protective film 8 containing a CF-based polymer generated by the CF-based etching gas. By protecting the side walls of the insulating layers 51 and 51A and the sacrifice layers 57 and 57A, damaged layers 51a and 57a generated on the side walls by the RIE method can be reduced.

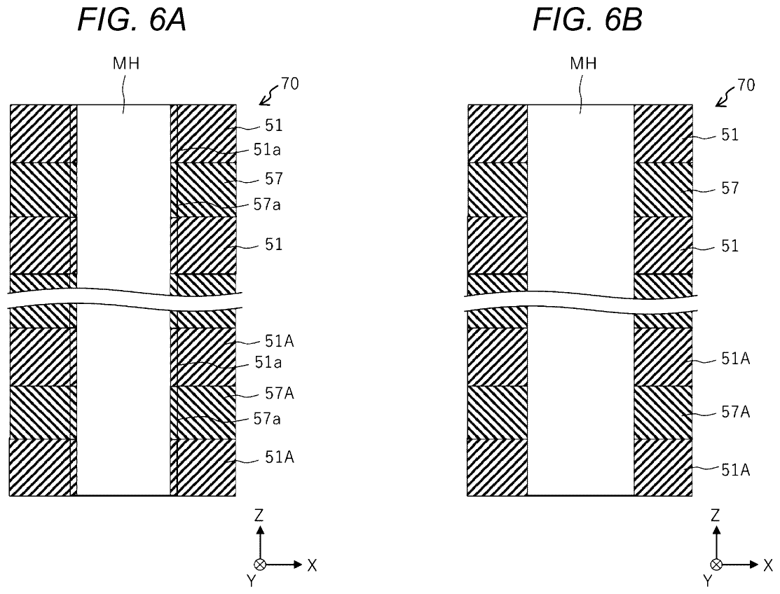

FIGS. 6A and 6B are cross-sectional views illustrating the method of manufacturing the semiconductor device 1 according to the first embodiment, following FIGS. 5A and 5B. After forming the memory hole MH, the protective film 8 is removed by ashing as illustrated in FIG. 6A. After removing the protective film 8, the damaged layers 51a and 57a are removed by a wet etching method using diluted hydrofluoric acid (DHF) as a chemical solution as illustrated in FIG. 6B, and the memory hole MH is widened.

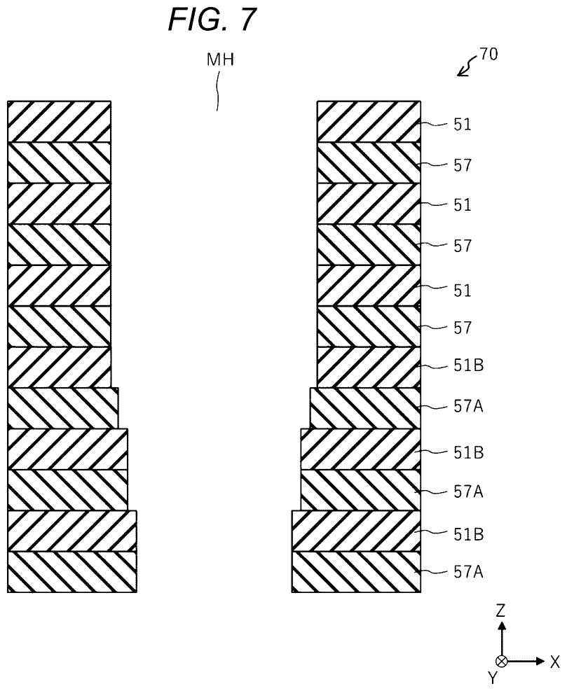

FIG. 7 is a detailed cross-sectional view of a method of manufacturing the semiconductor device 1 according to a comparative example. Here, when the RIE method is performed, tapering, in which the width (i.e., diameter) of the memory hole MH becomes smaller toward the lower layer side of the stacked film 70, occurs. As the depth of the memory holes MH is increased in order to increase a storage capacity of the memory cell array 11, the tapering of the memory holes MH becomes more remarkable. In order to reduce the tapering of the memory hole MH, it is desirable to increase the etching rate of wet etching for widening the memory hole MH on the lower layer side of the stacked film 70. However, when an insulating layer 51B on the lower end side does not contain phosphorus (P) as illustrated in FIG. 7, the etching rate of the insulating layer 51B on the lower end side is difficult to sufficiently increase. Even when the insulating layer 51B on the lower end side is a silicon oxide film (SiO₂) whose density is reduced by adjusting a balance of the pressure and weight of the process gas, the etching rate is difficult to sufficiently increase.

More specifically, between the formation of the stacked film 70 and the widening of the memory hole MH by wet etching, heat treatment (i.e., annealing treatment) for heating the substrate 16 may be performed for the purpose of reducing warpage of the substrate 16. In heat treatment, by heating the insulating layer 51B together with the substrate 16, the etching rate of the insulating layer 51B in wet etching decreases. Therefore, even when a low-density silicon oxide film (SiO₂) is used, it is difficult to sufficiently reduce the tapering of the memory hole MH. That is, with the insulating layer 51B that does not contain phosphorus (P), it is difficult to sufficiently reduce the variation in the width of the memory hole MH between the upper end side and the lower end side of the memory hole MH.

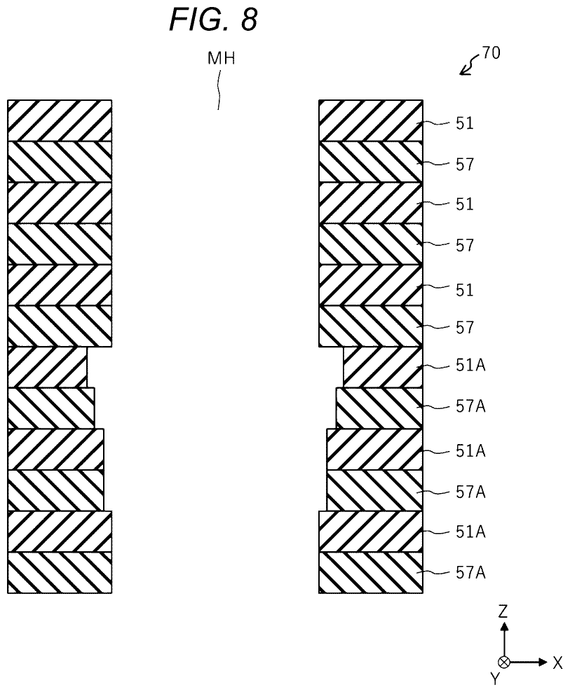

FIG. 8 is a detailed cross-sectional view of the method of manufacturing the semiconductor device 1 illustrated in FIG. 6B. On the other hand, as illustrated in FIG. 8, in the first embodiment, the insulating layer 51A on the lower layer side contains phosphorus (P). By making the insulating layer 51A on the lower end side contain phosphorus (P), the etching rate of the wet etching of the insulating layer 51A on the lower end side can be sufficiently increased. That is, the etching rate of the insulating layer 51A containing phosphorus (P) is hardly decreased even when heat treatment is performed. Therefore, the tapering of the memory hole MH widened by wet etching is sufficiently reduced. That is, with the insulating layer 51A containing phosphorus (P), the variation in the width of the memory hole MH between the upper end side and the lower end side of the memory hole MH can be sufficiently reduced.

In the example illustrated in FIG. 8, the width (i.e., diameter) of the memory hole MH in the radial direction perpendicular to the Z-direction (i.e., the X-direction and the Y-direction) is maximum at the position of the uppermost insulating layer 51A among the plurality of insulating layers 51A on the lower end side containing a Group V element. In other words, an inner perimeter of the memory hole MH is maximum at the position of the uppermost insulating layer 51A among the plurality of insulating layers 51A on the lower end side. Thus, the memory hole MH of the first embodiment has a point between the upper end and the lower end where the width is locally increased, but the memory hole MH as a whole has a more uniform width than the memory hole MH of the comparative example (see FIG. 7). Reflecting the shape of the memory hole MH, the width (i.e., diameter) of the columnar portion CL in the radial direction orthogonal to the Z-direction is maximum at the position of the uppermost insulating layer 51A among the plurality of insulating layers 51A on the lower end side.

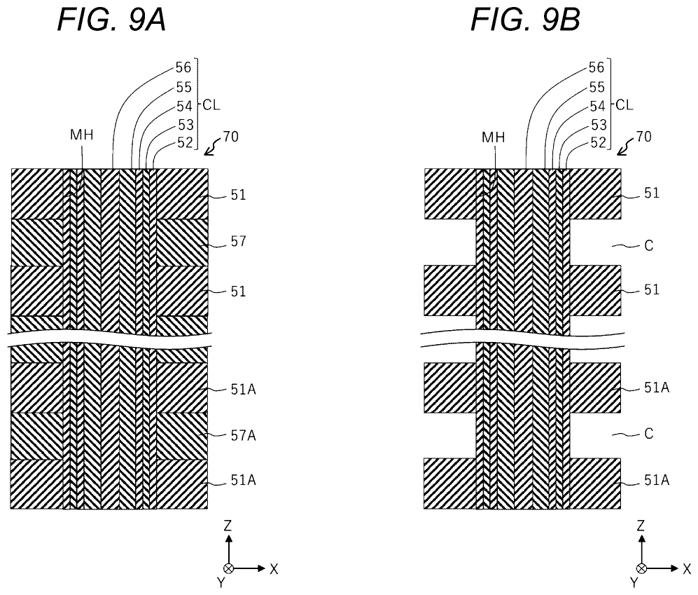

FIGS. 9A and 9B are cross-sectional views illustrating a method of manufacturing the semiconductor device 1 according to the first embodiment following FIGS. 6A and 6B. After the memory hole MH is widened, the columnar portion CL is embedded in the memory hole MH as illustrated in FIG. 9A.

That is, first, a block insulating film 52 is formed on each of side surfaces of the insulating layers 51 and 51A and the sacrifice layers 57 and 57A. The block insulating film 52 is, for example, a silicon oxide film (SiO₂). The block insulating film 52 is formed, for example, by the Atomic Layer Deposition (ALD) method using tris(dimethylamino)silane (TDMAS) gas. The block insulating film 52 may be formed on the side surface of the sacrifice layer 57 by directly oxidizing the side surface of the sacrifice layer 57 by radical oxidation.

After forming the block insulating film 52, the charge storage film 53 is formed on the side surface of the block insulating film 52 opposite to the insulating layers 51 and 51A and the sacrifice layers 57 and 57A. The charge storage film 53 is, for example, a silicon nitride film (SiN). The charge storage film 53 is formed, for example, by the ALD method using dichlorosilane (SiH₂Cl₂) gas and ammonia (NH₃) gas in a reduced pressure environment (2000 Pa or less) of 300° C. or more and 800° C. or less.

After forming the charge storage film 53, the tunnel insulating film 54 is formed on the side surface of the charge storage film 53 opposite to the block insulating film 52. The tunnel insulating film 54 is, for example, a silicon oxynitride film (SiON). The tunnel insulating film 54 is formed, for example, by the ALD method using hexachlorodisilane (HCD) gas, ammonia gas, and oxygen gas in a reduced pressure environment (2000 Pa or less) of 400° C. or more and 800° C. or less.

After forming the tunnel insulating film 54, the channel semiconductor film 55 is formed on the side surface of the tunnel insulating film 54 opposite to the charge storage film 53. The channel semiconductor film 55 is, for example, a silicon (Si) film. The channel semiconductor film 55 is formed, for example, by the CVD method using silane gas in a reduced pressure environment (2000 Pa or less) of 400° C. or more and 800° C. or less, and then crystallized by annealing. With this configuration, the silicon film changes from amorphous silicon to polysilicon.

After forming the channel semiconductor film 55, the core insulating film 56 is formed on the side surface of the channel semiconductor film 55 opposite to the tunnel insulating film 54. The core insulating film 56 is, for example, a silicon oxide film. The core insulating film 56 is, for example, formed by the CVD method using tetraethyl orthosilicate (TEOS).

After the columnar portion CL is embedded in the memory hole MH as described above, a groove (not illustrated) is formed in the stacked film 70. After forming the groove, the sacrifice layers 57 and 57A are removed by wet etching using the formed groove. For the wet etching, a chemical solution such as hot phosphoric acid is used. By removing the sacrifice layers 57 and 57A, a cavity C is formed between the adjacent insulating layers 51 and 51A as illustrated in FIG. 9B. In the cavity C, the surface of the insulating layer 51 in the Z-direction and the side surface of the block insulating film 52 are exposed.

After forming the cavity C, as illustrated in FIG. 2, the word line WL is formed to fill the cavity C.

As described above, the semiconductor device 1 according to the first embodiment includes the substrate 15, the stacked film 7, and the columnar portion CL. The stacked film 7 is provided above the substrate 15, and includes a plurality of insulating layers 51 and 51A and a plurality of word lines WL that are alternately stacked in the Z-direction intersecting the upper surface of the substrate 15. The columnar portion CL penetrates the stacked film 7 in the Z-direction. The concentration of the Group V element of the insulating layer 51A (i.e., the first insulating layer) on the lower end side out of the plurality of insulating layers 51 and 51A is higher than that of the insulating layer 51 (i.e., the second insulating layer) on the upper layer side out of the plurality of insulating layers 51 and 51A.

The method of manufacturing the semiconductor device 1 according to the first embodiment includes forming the stacked film 70 including the plurality of insulating layers 51 and 51A and the plurality of sacrifice layers 57 and 57A stacked alternately in the Z-direction intersecting the upper surface of the substrate 16 above the substrate 16. The method further includes forming the memory hole MH penetrating the stacked film 70 in the Z-direction. The method further includes processing the memory hole MH so that the width (i.e., diameter) of the memory hole MH increases in the radial direction orthogonal to the Z-direction. The insulating layer 51A on the lower end side is formed to have a higher concentration of the Group V element than the insulating layer 51 on the upper layer side.

With this configuration, even after heat treatment, the insulating layer 51A on the lower end side can maintain a high etching rate in wet etching that widens the memory hole MH. With this configuration, the tapering of the memory hole MH can be reduced. Therefore, according to the first embodiment, variation in the width of the memory hole MH (i.e., the columnar portion CL) between the upper end side and the lower end side of the memory hole MH can be reduced. By reducing the variation in the width of the memory hole MH, the threshold voltage of the memory cell array 11 can be made uniform. That is, the electrical characteristics of the semiconductor device 1 can be improved. The columnar portion CL can be appropriately embedded in the memory hole MH.

In the first embodiment, the Group V element may be phosphorus (P).

With this configuration, the insulating layer 51A can contain phosphorus (P), so that the insulating layer 51A can appropriately maintain a high etching rate in wet etching even after heat treatment. By using phosphorus (P) as the Group V element instead of nitrogen (N), which is the same element contained in the sacrifice layers 57 and 57A, the insulating layer 51A can be prevented from being removed together with the sacrifice layers 57 and 57A by a chemical solution when replacing the sacrifice layers 57 and 57A.

In the first embodiment, the concentration of the Group V element in the insulating layer 51A on the lower end side may be 1.9% or more.

With this configuration, the etching rate of the insulating layer 51A in wet etching can be further improved. Specifically, the etching rate of the insulating layer 51A can be increased to an etching rate equivalent to the etching rate of the sacrifice layer 57A made of a silicon oxide film containing oxygen.

In the first embodiment, the concentration of the Group V element in the insulating layer 51A on the lower end side may be 3.5% or less.

With this configuration, a breakdown voltage of the insulating layer 51A on the lower end side can be improved, so that leakage current between adjacent word lines WL can be reduced. Specifically, the breakdown voltage of the insulating layer 51A can be made higher than breakdown voltage of an insulating layer made of a low-density silicon oxide film.

In the first embodiment, the Group V element is contained in the insulating layer 51A on the lower end side, but is not contained in the insulating layer 51 on the upper layer side.

With this configuration, the etching rate of the insulating layer 51A on the lower end side can be locally increased, so that the tapering of the memory hole MH can be effectively reduced.

In the first embodiment, the formation of the memory hole MH may be performed using a reactive ion etching method, and the processing of the memory hole MH may be performed using a wet etching method.

With this configuration, the memory hole MH can be widened while removing the damaged layer formed on the side wall of the memory hole MH by the RIE method.

In the first embodiment, the sacrifice layer 55A on the lower end side may be formed to contain oxygen.

With this configuration, the etching rate of the sacrifice layer 55A on the lower end side in wet etching can be increased, so that the tapering of the memory hole MH can be more effectively reduced.

In the first embodiment, the formation of the memory hole MH may be performed while the side wall of the memory hole MH is protected with the protective film 8 formed on the side wall of the memory hole MH using etching gas.

With this configuration, the damaged layer of the side wall of the memory hole MH by the RIE can be reduced.

### Second Embodiment

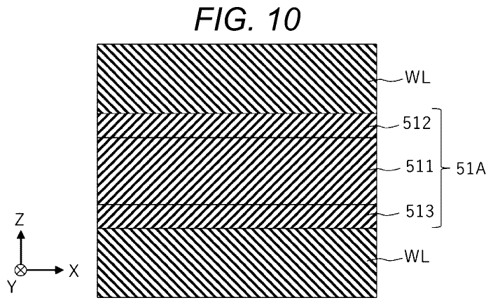

Next, a second embodiment for further improving the breakdown voltage of the insulating layer 51A on the lower end side will be described, focusing on the difference from the embodiment described above. FIG. 10 is a cross-sectional view illustrating a semiconductor device according to the second embodiment.

Thus, an example is described in which the insulating layer 51A on the lower end side entirely contains a Group V element. In contrast, in the example illustrated in FIG. 10, the insulating layer 51A on the lower end side partially contains the Group V element. Specifically, the insulating layer 51A on the lower end side includes a first insulating portion 511 containing a Group V element, a second insulating portion 512 provided on the first insulating portion 511 and not containing the Group V element, and a third insulating portion 513 provided under the first insulating portion 511 and not containing the Group V element.

The first insulating portion 511 is, for example, a silicon oxide film (SiO₂) containing phosphorus (P) as described above. The second insulating portion 512 and the third insulating portion 513 are, for example, existing silicon oxide films (SiO₂) that do not contain phosphorus (P). By providing the second insulating portion 512, the breakdown voltage of the insulating layer 51A on the lower end side can be improved. Furthermore, by providing the third insulating portion 513, the breakdown voltage of the insulating layer 51A on the lower end side can be further improved.

The thickness of the second insulating portion 512 and the third insulating portion 513 in the Z-direction is thinner than that of the first insulating portion 511. For example, the thickness of the second insulating portion 512 and the third insulating portion 513 is one-third or less of the thickness of the first insulating portion 511. By forming the second insulating portion 512 and the third insulating portion 513 to have a thickness thinner than the thickness of the first insulating portion 511, a decrease in the etching rate of wet etching can be prevented while maintaining the breakdown voltage of the insulating layer 51A on the lower end side.

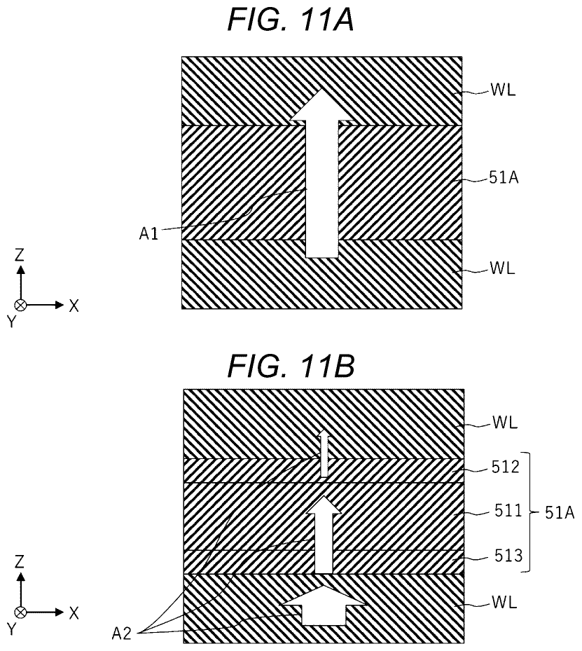

FIGS. 11A and 11B are cross-sectional views illustrating the prevention of leakage current by the semiconductor device 1 according to the second embodiment. When the insulating layer 51A on the lower end side contains a Group V element as a whole, it may be difficult to sufficiently ensure the breakdown voltage of the insulating layer 51A on the lower end side unless special measures are taken, such as keeping the concentration of the Group V element to 3.5% or less. In this case, as indicated by the arrow A1 in FIG. 11A, there is a concern that the leakage current flowing between the upper and lower word lines WL will become large.

In contrast, according to the second embodiment, since only the first insulating portion 511 of the insulating layer 51A on the lower end side contains a Group V element, the breakdown voltage of the insulating layer 51A on the lower end side can be ensured. With this configuration, as illustrated by the arrow A2 in FIG. 11B, the leakage current can be sufficiently reduced.

In addition, by providing the second insulating portion 512 and third insulating portion 513 made of the same material above and below the first insulating portion 511, etching resistance of the insulating layer 51A when replacing sacrifice layer 57A can be made uniform between the upper end and lower end of the insulating layer 51A. With this configuration, shape stability of the insulating layer 51A can be improved.

### Third Embodiment

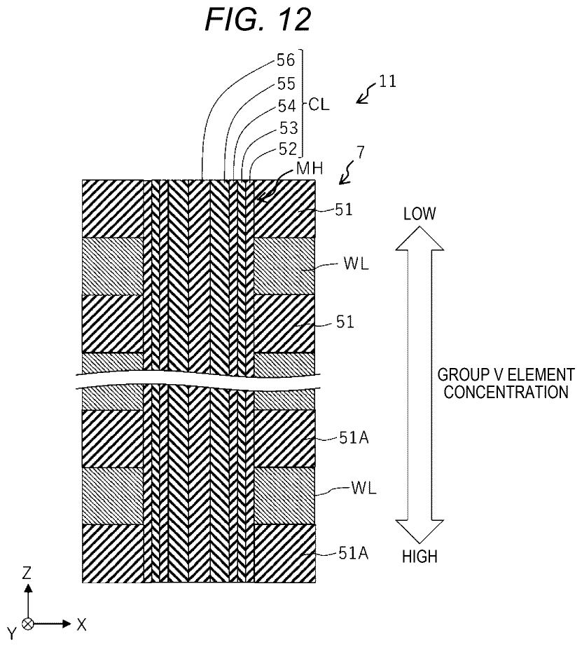

Next, an example in which all of the insulating layers 51 contain a Group V element will be described. FIG. 12 is a cross-sectional view illustrating a semiconductor device 1 according to a third embodiment. Thus, an example in which only the insulating layer 51A on the lower end side contains the Group V element is described. In contrast, in the example illustrated in FIG. 12, all of the insulating layers 51 to 51A from an uppermost layer to a lowermost layer contain the Group V element. The concentration of the Group V element may increase by a predetermined amount toward the lower layer side. According to the third embodiment, the concentration of the Group V element can be adjusted for each of the insulating layers 51 to 51A, so that the shape of the memory hole MH can be further improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a stacked film provided above the substrate and including a plurality of insulating layers and a plurality of electrode layers alternately stacked in a first direction intersecting an upper surface of the substrate; and
a columnar portion penetrating through the stacked film in the first direction,
wherein a concentration of a Group V element of at least one first one of the insulating layers on a first end side in the first direction is higher than a concentration of the Group V element of a second one of the insulating layers.

2. The semiconductor device according to claim 1,
wherein the Group V element includes phosphorus.

3. The semiconductor device according to claim 1,
wherein the concentration of the Group V element in the first insulating layer is equal to or greater than 1.9%.

4. The semiconductor device according to claim 3,
wherein the concentration of the Group V element in the first insulating layer is equal to or less than 3.5%.

5. The semiconductor device according to claim 1,
wherein the Group V element is contained in the first insulating layer and is not contained in the second insulating layer.

6. The semiconductor device according to claim 1,
wherein the Group V element is contained in both the first insulating layer and the second insulating layer.

7. The semiconductor device according to claim 1,
wherein the stacked film includes two or more of the first insulating layers, and
a width of the columnar portion in a second direction intersecting the first direction is a maximum at a position of an uppermost first insulating layer among the two or more first insulating layers.

8. The semiconductor device according to claim 1,
wherein the first insulating layer includes:
a first insulating portion containing the Group V element; and
a second insulating portion provided on the first insulating portion and not containing Group V element.

9. The semiconductor device according to claim 8,
wherein the first insulating layer further includes a third insulating portion provided under the first insulating portion and not containing the Group V element.

10. The semiconductor device according to claim 8,
wherein a thickness of the second insulating portion in the first direction is thinner than a thickness of the first insulating portion.

11. The semiconductor device according to claim 9,
wherein a thickness of the third insulating portion in the first direction is thinner than a thickness of the first insulating portion.

12. A method of manufacturing a semiconductor device, comprising:
forming a second stacked film above a second substrate, the second stacked film including a plurality of insulating layers and a plurality of sacrifice layers alternately stacked in a first direction intersecting an upper surface of the second substrate;
forming a hole penetrating through the second stacked film in the first direction; and
processing the hole, causing a width of the hole increases in a second direction intersecting the first direction,
wherein a concentration of a Group V element of at least a first one of the insulating layers on a lower end side along the first direction is higher than a concentration of the Group V element of a second one of the insulating layers.

13. The method according to claim 12,
wherein the step of forming a hole is performed using a reactive ion etching process.

14. The method according to claim 12,
wherein the step of processing the hole is performed using a wet etching process.

15. The method according to claim 12,
wherein at least a first one of the sacrifice layers on the lower end side includes oxygen.

16. The method according to claim 13,
wherein the step of forming a hole is performed, while protecting a side wall of the hole with a protective film formed on the side wall of the hole with etching gas.

17. The method according to claim 16, further comprising:
removing the protective film after forming the hole,
wherein the step of processing the hole is performed after removing the protective film.

18. The method according to claim 12, further comprising:
forming a columnar portion in the hole after processing the hole; and
replacing the sacrifice layer with an electrode layer after forming the columnar portion.
